(19) United States
(12) Patent Application Publication
(10) Pub. No.: US 2025/0393414 A1
(43) Pub. Date: Dec. 25, 2025

(54) DISPLAY DEVICE AND MANUFACTURING METHOD THEREOF

(71) Applicant: Samsung Display Co., LTD., Yongin-si (KR)

(72) Inventor: Young Jae JEON, Yongin-si (KR)

(21) Appl. No.: 19/169,239

(22) Filed: Apr. 3, 2025

(30) Foreign Application Priority Data
Jun. 21, 2024 (KR) 10-2024-0081151

(51) Int. Cl. H10K 59/124; H10K 59/00; H10K 59/12; H10K 59/122

(52) U.S. Cl. CPC H10K 59/124; H10K 59/1201; H10K 59/122; H10K 59/771

(57) ABSTRACT

A display device includes an insulating layer including a protrusion which is disposed between a first pixel and a second pixel that are next (adjacent) to each other and protrudes along a height direction; a first pixel electrode disposed in the first pixel and a second pixel electrode disposed in the second pixel on the insulating layer; and a common electrode disposed on the first pixel electrode and the second pixel electrode and connected across the first pixel and the second pixel. The common electrode defines an opening between the first pixel and the second pixel, and the opening of the common electrode may surround a sidewall of the protrusion.

This application claims priority to Korean Patent Application No. 10-2024-0081151, filed on Jun. 21, 2024, and all the benefits accruing therefrom under 35 U.S.C. § 119, the content of which in its entirety is herein incorporated by reference.

### BACKGROUND

### 1. Field

The disclosure relates to a display device and a manufacturing method thereof.

### 2. Description of the Related Art

A display device includes a liquid crystal display (“LCD”), a plasma display panel (“PDP”), an organic light emitting diode device (“OLED” device), a field emission display (“FED”), and an electrophoretic display device.

Emission display devices are attracting attention as next-generation display devices thanks to advantages such as a wide viewing angle, a fast response speed, and low power consumption as well as being lightweight and thin.

Recently, as high-resolution display devices are used, the size of one pixel is reduced and the distance between adjacent pixels is narrowed.

### SUMMARY

Embodiments attempt to provide a display device and a manufacturing method for the display device that is capable of preventing lateral current leakage in a high-resolution display device.

However, the problem to be solved by the embodiments is not limited to the above-described problem, and may be variously extended within the scope of the technical spirit included in the embodiments.

An embodiment provides a display device including: an insulating layer configured to include a protrusion which is disposed between a first pixel and a second pixel that are next (adjacent) to each other and protrudes along a height direction; a first pixel electrode disposed in the first pixel and a second pixel electrode disposed in the second pixel on the insulating layer; and a common electrode disposed on the first pixel electrode and the second pixel electrode and connected across the first pixel and the second pixel. The common electrode may define an opening between the first pixel and the second pixel, and the opening of the common electrode may surround a sidewall of the protrusion.

In an embodiment, the sidewall of the protrusion of the insulating layer may have an inclination of less than about 20 degrees with respect to the height direction.

In an embodiment, the display device may further include a separation pattern disposed on the protrusion of the insulating layer, and the separation pattern may include a first layer including the same material as that of the first pixel electrode and the second pixel electrode.

In an embodiment, the display device may further include a light emitting member disposed between the first and second pixel electrodes and the common electrode. The light emitting member may include a common layer having portions that are connected to each other across the first pixel and the second pixel. The common layer of the light emitting member may define the opening. In an embodiment, the separation pattern may further include a second layer including the same material as the common layer, and a third layer including the same material as that of the common electrode.

In an embodiment, the display device may further include a pixel defining layer defining pixel openings corresponding to each of the first pixel and the second pixel and a separation opening surrounding the protrusion of the insulating layer.

In an embodiment, the insulating layer may further include first protrusions overlapping each of the first pixel electrode and the second pixel electrode and protruding in the height direction. Sidewalls of the first protrusions may have substantially the same planar shape as that of each of the first pixel electrode and the second pixel electrode.

In an embodiment, the sidewalls of the first protrusions of the insulating layer may have an inclination of less than about 20 degrees with respect to the height direction.

In an embodiment, the sidewalls of the first protrusions of the insulating layer may be covered with the pixel defining layer.

In an embodiment, the insulating layer may have a trench defining the protrusion and the first protrusions. The separation opening of the pixel defining layer may be defined within the trench.

In an embodiment, the opening of the common electrode may be defined within the trench.

In an embodiment, the opening of the common electrode may be surrounded by the separation opening of the pixel electrode when viewed from above in the height direction.

In an embodiment, the separation pattern and the sidewalls of the protrusions may not be covered with the pixel defining layer.

An embodiment of the disclosure provides a manufacturing method for a display device, and the method includes forming a transistor on a substrate; stacking an insulating layer on the transistor; forming a first pixel electrode and a second pixel electrode of a first pixel and a second pixel next (adjacent) to each other on the insulating layer; and forming a separation pattern disposed between the first pixel electrode and the second pixel electrode; forming first protrusions that overlap each of the first pixel electrode and the second pixel electrode and protrude in the height direction, a second protrusion overlapping the separation pattern and protruding in the height direction, and a trench defining the first protrusion and the second protrusion by ashing the insulating layer using the first pixel electrode, the second pixel electrode, and the separation pattern as masks; forming a pixel defining layer defining pixel openings overlapping each of the first pixel electrode and the second pixel electrode and a separation opening surrounding the second protrusion; and stacking a light emitting member and a common electrode on the pixel defining layer. The common electrode may define an opening between the first pixel and the second pixel and surrounding a sidewall of the second protrusion.

In an embodiment, the sidewall of the second protrusion of the insulating layer may be formed to have an inclination of less than about 20 degrees with respect to the height direction.

In an embodiment, the separation pattern may include a first layer formed from the same layer as that from which the first pixel electrode and the second pixel electrode are formed, a second layer disposed on the first layer and formed from the same layer as that from which the light emitting member is formed, and a third layer disposed on the second layer and formed from the same layer as that from which the common electrode is formed.

In an embodiment, the sidewalls of the first protrusions of the insulating layer may be covered with the pixel defining layer.

In an embodiment, the light emitting member may include a common layer having portions that are connected to each other across the first pixel and the second pixel, and the common layer of the light emitting member may define the opening.

By embodiments, a display device and a method of manufacturing the display device may prevent lateral current leakage in a high-resolution display device.

However, it is obvious that the effect of the embodiments is not limited to the above-described effect and may be variously extended without departing from the spirit and scope of the embodiments.

### BRIEF DESCRIPTION OF THE DRAWINGS

The above and other embodiments, advantages and features of this disclosure will become more apparent by describing in further detail embodiments thereof with reference to the accompanying drawings.

FIG. 1 illustrates a schematic perspective view of an embodiment of a display device.

FIG. 2 illustrates a cross-sectional view taken along line I-I′ of FIG. 1.

FIG. 3 illustrates a cross-sectional view of a region of FIG. 1.

FIG. 4 illustrates a schematic top plan view showing an embodiment of a display area of a display device.

FIG. 5 illustrates a schematic cross-sectional view taken along line I-I′ of FIG. 4.

FIG. 6 illustrates a schematic cross-sectional view of an embodiment of a light emitting member of a display device.

FIG. 7 to FIG. 12 illustrate schematic cross-sectional views showing an embodiment of a manufacturing method for a display device.

FIG. 13 to FIG. 16 illustrate a schematic top plan view showing a portion of a display device according to other embodiments.

FIG. 17 and FIG. 18 illustrate a cross-sectional view of one pixel of a display device according to other embodiments.

FIG. 19 is a block diagram illustrating an embodiment of an electronic device.

FIG. 20 is a view illustrating an embodiment of the electronic device of FIG. 19 implemented as a smartphone.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

To clearly describe the disclosure, parts that are irrelevant to the description are omitted, and like numerals refer to like or similar components throughout the specification.

The accompanying drawings are provided only in order to allow embodiments disclosed in the specification to be easily understood and are not to be interpreted as limiting the spirit disclosed in the specification, and it is to be understood that the embodiments include all modifications, equivalents, and substitutions without departing from the scope and spirit of the embodiments.

Further, since sizes and thicknesses of constituent members shown in the accompanying drawings are arbitrarily given for better understanding and ease of description, the disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly stated to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, “connected” does not only mean that two or more components are directly connected, but may also mean that two or more components are connected indirectly through other components, physically connected as well as being electrically connected, or that two or more components are referred to by different names depending on the location or function, but are unitary.

“About” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, various embodiments and variations will be described in detail with reference to the drawings.

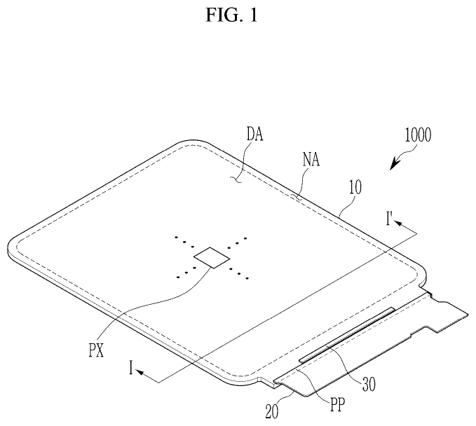

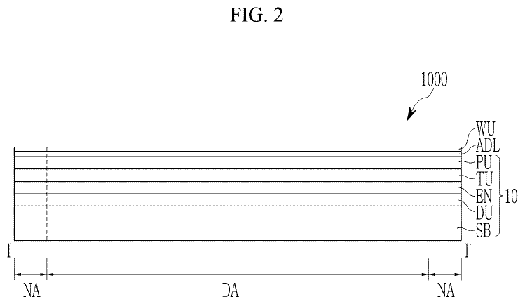

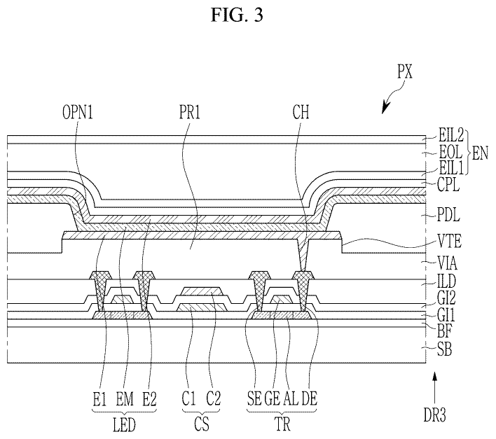

A display device in an embodiment will now be briefly described with reference to FIG. 1 to FIG. 3. FIG. 1 illustrates a schematic perspective view of an embodiment of a display device, FIG. 2 illustrates a cross-sectional view taken along line I-I′ of FIG. 1, and FIG. 3 illustrates a cross-sectional view of a region of FIG. 1.

Referring to FIG. 1, the display device 1000 may include a display panel 10, a flexible printed circuit film 20 bonded to the display panel 10, a driving unit including an integrated circuit chip 30, etc.

The display panel 10 may include a display area DA corresponding to a screen on which an image is displayed and a non-display area NA, and circuits and/or signal lines for generating and/or transferring various signals and voltages applied to the display area DA are disposed in the non-display area NA. The non-display area NA may be disposed to surround a periphery of the display area DA. In FIG. 1, the inside and outside of a dotted quadrangle may correspond to the display area DA and the non-display area NA, respectively.

The display area DA of the display panel 10 may include a plurality of pixels PX. In addition, the display area DA may include signal lines such as a gate line (also referred to as a scan line), a data line, and a driving voltage line. The gate line, the data line, the driving voltage line, etc., are connected to each pixel PX, and each pixel PX may receive a gate signal (also referred to as a scan signal), a data voltage, and a driving voltage (also referred to as a first power voltage or a high-potential power voltage) from these signal lines. The pixels PX may include light emitting elements such as a light emitting diodes.

A touch sensor for detecting a user's touch and/or a non-contact touch may be disposed in the display area DA. Although the display area DA having a substantially quadrangular shape with a rounded edge is illustrated, the display area DA may have various shapes such as a polygonal shape, a circular shape, an elliptical shape, or the like.

Although the display area DA is shown as flat, the disclosure is not limited thereto, and the display area DA may include a curved portion.

A pad portion PP in which pads for receiving signals from the outside of the display panel 10 are arranged may be disposed in the non-display area NA of the display panel 10. The pad portion PP may be disposed to extend in a first direction x along one edge of the display panel 10. The flexible printed circuit film 20 is bonded to the pad portion PP, and pads of the flexible printed circuit film 20 may be electrically connected to pads of the pad portion PP.

A driving unit may be disposed in the non-display area NA of the display panel 10 to generate and/or process various signals for driving the display panel 10. The driving unit may include a data driver for applying a data voltage to the data line, a gate driver for applying a gate signal to the gate line, and a signal controller for controlling the data driver and the gate driver. The pixels PX may receive the data voltage at a predetermined timing depending on the gate signal generated by the gate driver. The gate driver may be integrated in the display panel 10 and may be disposed on at least one side of the display area DA. The data driver and the signal controller may be provided as an integrated circuit chip (also referred to as a driving integrated chip (“IC”) chip) 30, and the integrated circuit chip 30 may be disposed (e.g., mounted) in the non-display area NA of the display panel 10. The integrated circuit chip 30 may be disposed (e.g., mounted) on the flexible printed circuit film 20 or the like to be electrically connected to the display panel 10.

Hereinafter, a display device 1000 in an embodiment of the disclosure will be described by taking an organic light emitting diode device in an embodiment, but the display device 1000 of the disclosure is not limited thereto. The display device 1000 in another embodiment of the disclosure may be an inorganic light emitting display or an inorganic electroluminescent (“EL”) display device, or a display device such as a quantum dot light emitting display. In an embodiment, a light emitting layer of a display element provided in the display device 1 may include an organic material, an inorganic material, quantum dots, an organic material and quantum dots, or an inorganic material and quantum dots, for example.

Referring to FIG. 2, the display device 1000 in an embodiment of the disclosure may include a display panel 10 including a display layer DU, an encapsulation layer EN, a touch sensor layer TU, an anti-reflective layer PU disposed on the substrate SB, a window layer WU, and an adhesive member ADL between the display panel 10 and the window layer WU. In the illustrated embodiment, the display panel 10 is shown as including the display layer DU, the encapsulation layer EN, the touch sensor layer TU, and the anti-reflective layer PU, but at least some of the display layer DU, the encapsulation layer EN, the touch sensor layer TU, and the anti-reflective layer PU may be coupled to each other through an adhesive member.

In another embodiment, the anti-reflective layer PU and the window layer WU may be replaced with another component, or may be omitted.

The display layer DU may include a plurality of pixels PX. The encapsulation layer EN may encapsulate a display element included in each of the pixels PX—for example, light emitting elements LED. The encapsulation layer EN may include at least one inorganic encapsulation layer and/or at least one organic encapsulation layer.

The display layer DU generates an image, and the touch sensor layer TU acquires external input—for example, coordinate information of the touch area.

Although not shown, the display panel 10 in an embodiment of the disclosure may further include a protective member disposed on a back surface of the substrate SB. The protective member and the substrate SB may be coupled through an adhesive member.

The anti-reflective layer PU may reduce reflectance of external light incident from an upper side of the window layer WU. In an embodiment, the anti-reflective layer PU may include a black matrix and a color filter, for example. The color filter may be disposed to correspond to a light emitting area of each pixel, and the black matrix may be disposed to correspond to the non-light emitting area between each pixel.

In the illustrated embodiment, the anti-reflective layer PU is shown disposed on the touch sensor layer TU, but in another embodiment, the anti-reflective layer PU may be disposed on the encapsulation layer EN, and a touch sensor layer TU may be disposed on the anti-reflective layer PU.

Referring to FIG. 3, each pixel PX of the display panel 10 may include a transistor TR disposed on the substrate SB and the light emitting element LED connected to the transistor TR.

The substrate SB may include or consist of a material such as glass. The substrate SB may be a flexible substrate including a polymer resin such as polyimide, polyamide, or polyethylene terephthalate.

A buffer layer BF may be disposed on the substrate SB. The buffer layer BF may improve the characteristics of the semiconductor layer by blocking impurities from the substrate SB when the semiconductor layer is formed, and may flatten a surface of the substrate SB to relieve stress applied to the semiconductor layer. The buffer layer BF may include an inorganic insulating material such as silicon nitride (SiNₓ), silicon oxide (SiOₓ), and silicon oxynitride (SiOₓN_{y}), and may be a single layer or multiple layers. The buffer layer BF may include amorphous silicon (Si).

A semiconductor layer AL of the transistor TR may be disposed on the buffer layer BF. The semiconductor layer AL may include a first region and a second region, and a channel region between the first region and the second region. The semiconductor layer AL may include any one of amorphous silicon, polycrystalline silicon, and an oxide semiconductor. In an embodiment, the semiconductor layer AL may include low-temperature polysilicon (“LTPS”), and may include an oxide semiconductor material including at least one of zinc (Zn), indium (In), gallium (Ga), or tin (Sn). In an embodiment, the semiconductor layer AL may include an indium-gallium-zinc oxide (“IGZO”).

A first gate insulating layer GI1 may be disposed on the semiconductor layer AL. The first gate insulating layer GI1 may include an inorganic insulating material such as silicon nitride, silicon oxide, and silicon oxynitride, and may be a single layer or multiple layers.

The first gate conductive layer, which may include a gate electrode GE of the transistor TR, and a first electrode C1 of a capacitor CS, may be disposed on the first gate insulating layer GI1. The first gate conductive layer may include molybdenum (Mo), aluminum (Al), copper (Cu), titanium (Ti), or the like, and may be a single layer or multiple layers.

A second gate insulating layer GI2 may be disposed on the first gate conductive layer. The second gate insulating layer GI2 may include an inorganic insulating material such as silicon nitride, silicon oxide, and silicon oxynitride, and may be a single layer or multiple layers.

A second gate conductive layer that may include a second electrode C2 of the capacitor CS or the like may be disposed on the second gate insulating layer GI2. The second gate conductive layer may include molybdenum (Mo), aluminum (Al), copper (Cu), titanium (Ti), or the like, and may be a single layer or multiple layers.

An inter-insulating layer ILD may be disposed on the second gate insulating layer GI2 and the second gate conductive layer. The inter-insulating layer ILD may include an inorganic insulating material such as silicon nitride, silicon oxide, and silicon oxynitride, and may be a single layer or multiple layers.

A first data conductive layer that may include a first electrode SE and a second electrode DE of the transistor TR or the like may be disposed on the inter-insulating layer ILD. The first electrode SE and the second electrode DE may be respectively connected to a first region and a second region of the semiconductor layer AL through contact holes in the insulating layers GI1, GI2, and ILD. One of the first electrode SE and the second electrode DE may serve as a source electrode, and a remaining (the other) one may serve as a drain electrode. The first data conductive layer may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like, and may be a single layer or multiple layers. In an embodiment, the first data conductive layer may include a lower layer including a refractory metal such as molybdenum, chromium, tantalum, or titanium, an intermediate layer including a metal having relatively low resistivity such as aluminum, copper, or silver, and an upper layer including a refractory metal. In an embodiment, the third conductive layer may have a triple-layer structure of, e.g., titanium (Ti)/aluminum (Al)/titanium (Ti).

A planarization layer VIA may be disposed on the first data conductive layer. The planarization layer VIA may be an organic insulating layer. The planarization layer VIA may include an organic insulating material such as a general-purpose polymer such as poly (methyl methacrylate) and polystyrene, a polymer derivative having a phenolic group, an acrylic polymer, an imide-based polymer (e.g., polyimide), and a siloxane-based polymer.

A pixel electrode E1 may be disposed on the planarization layer VIA. The pixel electrode E1 may be electrically connected to the second electrode DE of the transistor TR through the contact hole CH in the planarization layer VIA, to receive a driving current that controls the brightness of the light emitting element LED.

The transistor TR to which the pixel electrode E1 is connected may be a driving transistor or another transistor that is electrically connected to the driving transistor. The pixel electrode E1 may include or consist of a reflective conductive material or a translucent conductive material, or may include or consist of a transparent conductive material. The pixel electrode E1 may include a transparent conductive material such as indium tin oxide (“ITO”) or indium zinc oxide (“IZO”). The pixel electrode E1 may include a metal such as lithium (Li), calcium (Ca), aluminum (AI), silver (Ag), magnesium (Mg), or gold (Au), or a metal alloy. The pixel electrode E1 may have a multi-layered structure, and may have a triple-layer structure of, e.g., ITO/silver (Ag)/ITO.

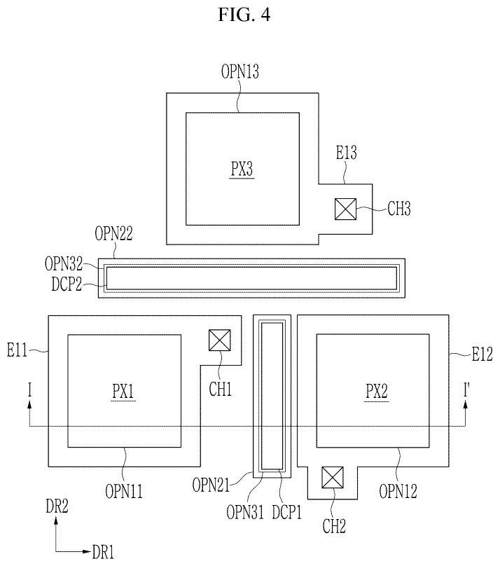

The planarization layer VIA may include a first protrusion PR1 overlapping the pixel electrode E1 and having substantially the same planar shape as that of the pixel electrode E1, and a trench VTE defining the first protrusion PR1 may be formed in a portion of the planarization layer VIA. The planarization layer VIA may further have second protrusions PR2 that overlap separation patterns DCP1 (refer to FIG. 4) and DCP2 (refer to FIG. 4) and have substantially the same planar shape as that of the separation patterns DCP1 and DCP2, which will be described later, and the second protrusions PR2 may also be defined by the trench VTE formed in a portion of the planarization layer VIA.

A pixel defining layer PDL may be disposed on the planarization layer VIA. The pixel defining layer PDL may be an organic insulating layer. The pixel defining layer PDL may define a pixel opening OPN1 overlapping the first electrode E1. The pixel opening OPN1 of the pixel defining layer PDL may define a light emitting area of the display device. The pixel defining layer PDL may further define separation openings OPN2 surrounding the separation patterns DCP1 and DCP2 and disposed in a region between neighboring pixels, which will be described later.

A light emitting member EM of the light emitting element LED may be disposed on the pixel electrode E1. The light emitting member EM may include a common layer that is interconnected between neighboring pixels and disposed commonly in the neighboring pixels.

A common electrode E2 of the light emitting element LED may be disposed on the light emitting member EM. The common electrode E2 may include or consist of a relatively low work function metal such as calcium (Ca), barium (Ba), magnesium (Mg), aluminum (AI), silver (Ag), or a metal alloy, as a thin layer to have light transmittance. The common electrode E2 may include a transparent conductive oxide such as ITO or IZO. A common voltage may be applied to the common electrode E2.

The pixel electrode E1, the light emitting member EM, and the common electrode E2 of each pixel PX may form a light emitting element LED such as an organic light emitting diode or an inorganic light emitting diode. The pixel electrode E1 may be an anode of the light emitting element LED, and the common electrode E2 may be a cathode of the light emitting element LED.

A capping layer CPL may be disposed on the common electrode E2. The capping layer CPL may increase light efficiency by adjusting a refractive index. The capping layer CPL may be disposed to cover an entirety of the common electrode E2. The capping layer CPL may include an organic insulating material, or may include an inorganic insulating material.

The encapsulation layer EN may be disposed on the capping layer CPL. The encapsulation layer EN may encapsulate a light emitting element LED to prevent moisture or oxygen from penetrating from the outside. The encapsulation layer EN may be a thin-film encapsulation layer including one or more inorganic layers EIL1 and EIL2 and one or more organic layers EOL.

A touch sensor layer (not illustrated) including touch electrodes may be disposed on the encapsulation layer EN. The touch electrodes may have a mesh shape defining an opening overlapping the light emitting element LED. An anti-reflection layer (not illustrated) for reducing external light reflection may be disposed on the touch sensor layer.

Each pixel PX of the display panel 10 shown in FIG. 3 is merely one example, and various changes are possible in the embodiments. Although one transistor TR is shown in FIG. 3, the disclosure is not limited thereto, and each pixel PX may include a plurality of transistors.

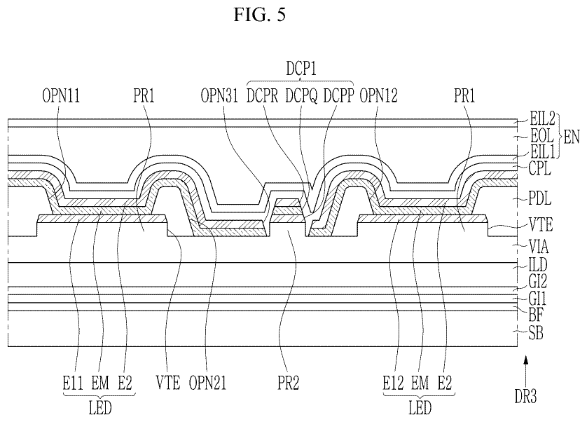

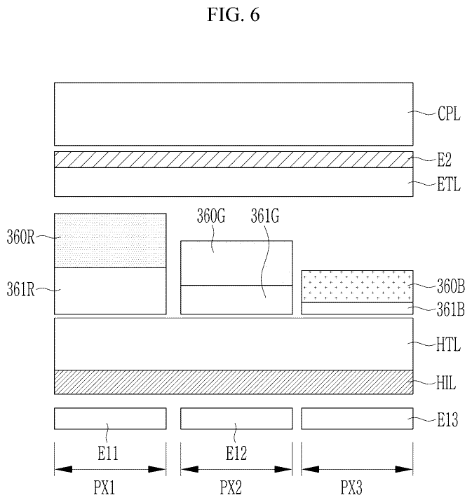

The display area of the display device in an embodiment will be described in more detail with reference to FIG. 4 to FIG. 6. FIG. 4 illustrates a schematic top plan view showing an embodiment of a display area of a display device, FIG. 5 illustrates a schematic cross-sectional view taken along line I-I′ of FIG. 4, and FIG. 6 illustrates a schematic cross-sectional view of a light emitting member of a display device.

Referring to FIG. 4, the display area of the display device in an embodiment may include a first pixel PX1, a second pixel PX2, and a third pixel PX3. Each of the first pixel PX1, the second pixel PX2, and the third pixel PX3 may include at least one transistor TR and a light emitting element LED connected thereto.

In an embodiment, the first pixel PX1 may emit red light, the second pixel PX2 may emit green light, and the third pixel PX3 may emit blue light, but the disclosure is not limited thereto. The display device may include light emitting areas that emit red light, green light, and blue light, and a non-light emitting area other than the light emitting area.

In an embodiment, the first pixel PX1, the second pixel PX2, and the third pixel PX3 may have different areas.

In an embodiment, each of the first pixel PX1, the second pixel PX2, and the third pixel PX3 is shown in a quadrangular shape, but the disclosure is not limited thereto, and may be modified to have various shapes. In addition, each of the first pixel PX1, the second pixel PX2, and the third pixel PX3 is shown in a quadrangular shape with different areas, but the disclosure is not limited thereto, and may be modified to have various areas. In addition, arrangement of pixels in which the first pixel PX1 and the second pixel PX2 are next (adjacent) to each other along the first direction DR1, the first pixel PX1 and the third pixel PX3 are next (adjacent) to each other along the second direction DR2, and the second pixel PX2 and the third pixel PX3 are next (adjacent) to each other along the second direction DR2 is shown, but the disclosure is not limited thereto, and the first pixel PX1, the second pixel PX2, and the third pixel PX3 may be arranged in various forms.

Referring to FIG. 5 along with FIG. 4, the display area of the display device in an embodiment may include a plurality of separation patterns DCP1 and DCP2.

The separation patterns DCP may include a first separation pattern DCP1 disposed between the first pixel PX1 and the second pixel PX2, and may include a second separation pattern DCP2 disposed between the third pixel PX3 and the first pixel PX1 and the second pixel PX2.

A pixel electrode E11 of the first pixel PX1 may be connected to a transistor (not shown) through a contact hole CH1, a pixel electrode E12 of the second pixel PX2 may be connected to a transistor (not shown) through a contact hole CH2, and a pixel electrode E13 of the third pixel PX3 may be connected to a transistor (not shown) through a contact hole CH3.

The planarization layer VIA may include first protrusions PR1 overlapping the pixel electrodes E11, E12, and E13 and having substantially the same planar shape as that of the pixel electrodes E11, E12, and E13, and second protrusions PR2 overlapping the separation patterns DCP1 and DCP2 and having substantially the same planar shape as that of the separation patterns DCP1 and DCP2.

The first protrusions PR1 and the second protrusions PR2 of the planarization layer VIA may be defined by the trench VTE in a portion of the planarization layer VIA.

The sidewalls of the first and second protrusions PR1 and PR2 of the planarization layer VIA may be inclined to have an angle of less than about 20 degrees with respect to the third direction (also referred to as a height direction) DR3.

The pixel defining layer PDL may define a first pixel opening OPN11 overlapping the pixel electrode E11 of the first pixel PX1, a second pixel opening OPN12 overlapping the pixel electrode E12 of the second pixel PX2, and a third pixel opening OPN13 overlapping the pixel electrode E13 of the third pixel PX3.

In addition, the pixel defining layer PDL may define a first separation opening OPN21 surrounding the first separation pattern DCP1 and a second separation opening OPN22 surrounding the second separation pattern DCP2.

The first separation opening OPN21 and the second separation opening OPN22 of the pixel defining layer PDL may surround the second protrusions PR2 of the planarization layer VIA and may be disposed in the trench VTE of the planarization layer VIA, and the second protrusions PR2 of the planarization layer VIA may be spaced apart from the pixel defining layer PDL by the first separation opening OPN21 and the second separation opening OPN22 of the pixel defining layer PDL.

The sidewalls of the first protrusions PR1 of the planarization layer VIA, which overlap the pixel electrodes E11, E12, and E13 and have substantially the same planar shape as that of the pixel electrodes E11, E12, and E13, may be covered by the pixel defining layer PDL. However, the sidewalls of the second protrusions PR2 of the planarization layer VIA, which overlap the separation patterns DCP1 and DCP2 and have substantially the same planar shape as that of the separation patterns DCP1 and DCP2, may be spaced apart from the pixel defining layer PDL and may not be covered by the pixel defining layer PDL.

A common layer of the light emitting member EM and the common electrode E2 of the first pixel PX1, the second pixel PX2, and the third pixel PX3 may define a first opening OPN31 and a second opening OPN32 disposed within the first separation opening OPN21 and the second separation opening OPN22.

When the light emitting member EM and the common electrode E2 are stacked on the second protrusions PR2 of the planarization layer VIA that are not covered by the pixel defining layer PDL, the common layer of the light emitting member EM and the common electrode E2 may be discontinuously formed to be broken on the sidewalls of the second protrusions PR2 of the planarization layer VIA by an inclination angle of the second protrusions PR2 of the planarization layer VIA, and a portion disposed on the second protrusions PR2 and a portion disposed in the trench VTE of the planarization layer VIA may be separated from each other, and thus the common layer of the light emitting member EM and the common electrode E2 may define the first opening OPN31 and the second opening OPN32.

The first opening OPN31 and the second opening OPN32 of the common layer of the light emitting member EM and the common electrode E2 may have a planar shape surrounding the sidewalls of the second protrusions PR2 of the planarization layer VIA.

When a plane formed by an intersection of the first direction DR1 and the second direction DR2 is viewed from above (in a plan view such as a top view), the first separation opening OPN21 and the second separation opening OPN22 of the pixel defining layer PDL may surround the first opening OPN31 and the second opening OPN32 of the common layer of the light emitting member EM and the common electrode E2, and the first opening OPN31 and the second opening OPN32 of the common layer of the light emitting member EM and the common electrode E2 may surround the first separation pattern DCP1 and the second separation pattern DCP2.

In an embodiment, edges of the first opening OPN31 and the second opening OPN32 of the common layer of the light emitting member EM and the common electrode E2 and edges of the first separation pattern DCP1 and the second separation pattern DCP2 may be substantially aligned along the third direction DR3, but the disclosure is not limited thereto.

In an embodiment, when a plane formed by an intersection of the first direction DR1 and the second direction DR2 is viewed from above, the first opening OPN31 and the second opening OPN32 of the common layer of the light emitting member EM and the common electrode E2 may have substantially the same planar shape as that of the first separation pattern DCP1 and the second separation pattern DCP2, but the disclosure is not limited thereto.

The first separation pattern DCP1 and the second separation pattern DCP2 may include a first layer DCPP formed from the same layer as that from which the pixel electrodes E11, E12, and E13 of the pixels PX1, PX2, and PX3 are formed, a second layer DCPQ formed from the same layer as that from which the light emitting member EM is formed, and a third layer DCPR formed from the same layer as that from which the common electrode E2 is formed in a manufacturing process. That is, the first layer DCPP may include the same material as that of the pixel electrodes E11, E12, and E13 of the pixels PX1, PX2, and PX3, the second layer DCPQ may include the same material as that of the light emitting member EM, and the third layer DCPR may include the same material as that of the common electrode E2 in a final structure.

As described above, when the light emitting member EM and the common electrode E2 are stacked on the second protrusions PR2 of the planarization layer VIA that are not covered by the pixel defining layer PDL, by the inclination angle of the second protrusions PR2 of the planarization layer VIA, the light emitting member EM and the common electrode E2 may be discontinuously formed on the sidewalls of the second protrusions PR2 of the planarization layer VIA to be broken, and a portion of the broken light emitting member EM and the portion of the broken common electrode E2 may remain on the second protrusions PR2 and become the second layer DCPQ and the third layer DCPR of the separation patterns DCP1 and DCP2.

According to the embodiment, by the second protrusions PR2 of the planarization layer VIA, which is not covered by the pixel defining layer PDL and has sidewalls with a relatively large slope, the light emitting member EM and the common electrode E2 may be discontinuously formed to be broken on the sidewalls of the second protrusions PR2 of the planarization layer VIA, and the common layer of the light emitting member EM and the common electrode E2 may define openings OPN31 and OPN32 having substantially the same planar shape as that of the second protrusions PR2. In this way, the common layer of the neighboring pixels PX1, PX2, and PX3—for example, the common layer of the light emitting member EM and the common electrode E2—define openings OPN31 and OPN32 disposed in the non-light emitting area, so lateral leakage current in the high-resolution structure may be prevented by partially disconnecting neighboring pixels.

In relation to this, with reference to FIG. 6, a structure of the light emitting element LED of the pixels and the lateral leakage current of the plurality of pixels will be described in more detail. In FIG. 6, a configuration common to each of the pixels PX1, PX2, and PX3 is shown as a single unit.

Referring to FIG. 6, a hole injection layer HIL and a hole transport layer HTL are disposed on the first electrodes E11, E12, and E13 of each of the pixels PX1, PX2, and PX3. The hole injection layer HIL is commonly disposed at each of the pixels PX1, PX2, and PX3. The hole transport layer HTL is also commonly disposed at each of the pixels PX1, PX2, and PX3. The common layer of the light emitting member EM defining the first opening OPN31 and the second opening OPN32 described above may include at least one of the hole injection layer HIL and the hole transport layer HTL that are commonly disposed in each of the pixels PX1, PX2, and PX3.

The first pixel PX1 may include a first auxiliary layer 361R and a first light emitting layer 360R. The second pixel PX2 may also include a second auxiliary layer 361G and a second light emitting layer 360G. The third pixel PX3 may also include a third auxiliary layer 361B and a third light emitting layer 360B.

An electron transport layer ETL may be disposed on each of the first light emitting layer 360R, the second light emitting layer 360G, and the third light emitting layer 360B. The electron transport layer ETL is commonly disposed in each of the pixels PX1, PX2, and PX3.

The common electrode E2 may be disposed on the electron transport layer ETL. The common electrode E2 may be commonly disposed in each of the pixels PX1, PX2, and PX3.

In this way, each of the pixels PX1, PX2, and PX3 may apply a common hole injection layer HIL to improve a hole injection characteristic. In this case, the hole injection layer HIL may be a doped hole transport layer HTL. That is, the hole injection layer HIL, which is a doped layer, may have higher electrical conductivity than that of the hole transport layer. Accordingly, a side leakage current problem may occur due to conductive characteristics.

When leakage current occurs in this way, pixel efficiency decreases and color purity deteriorates, and neighboring pixels are weakly lit due to leakage current, which may cause color mixing. In particular, in the case of relatively high resolution, since a distance between neighboring pixels is narrow, such a leakage current problem may appear more pronounced.

However, the display device in the embodiment may include the second protrusions PR2 of the planarization layer VIA having sidewalls with a relatively large slope in a non-light emitting area between neighboring pixels, and the separation patterns DCP1 and DCP2 disposed on the second protrusions PR2 and having substantially the same planar shape as that of the second protrusions PR2, the sidewalls of the second protrusions PR2 of the planarization layer VIA may not be covered by the pixel defining layer PDL, and the common layer of the light emitting member EM and the common electrode E2 may define the first opening OPN31 and the second opening OPN32 surrounding the outer portions of the separation patterns DCP1 and DCP2 and the sidewalls of the second protrusions PR2 of the planarization layer VIA.

Accordingly, the leakage current may be reduced by short-circuiting the common layer of the light emitting member EM and the common electrode E2 between neighboring pixels. In addition, regions of the first opening OPN31 and the second opening OPN32 may correspond to some areas of the non-light emitting areas between neighboring pixels, to prevent a voltage drop of the common voltage applied to the common electrode E2 according to the first opening OPN31 and the second opening OPN32, stably driving a high-resolution display device.

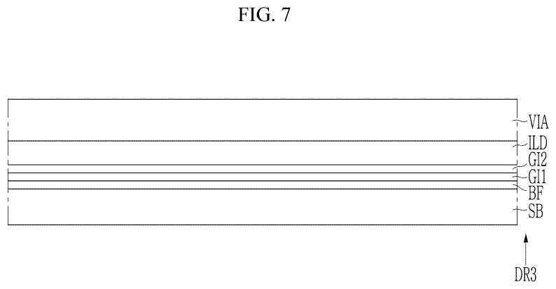

Next, a manufacturing method for a display device in an embodiment will be described with reference to FIG. 7 to FIG. 12 along with FIG. 4 to FIG. 6. FIG. 7 to FIG. 12 illustrate schematic cross-sectional views showing a manufacturing method for a display device.

Referring to FIG. 7 along with FIG. 3, a buffer layer BF may be disposed on the substrate SB, a semiconductor layer AL may be disposed on the buffer layer BF, a first gate insulating layer GI1 may be disposed on the semiconductor layer AL, a first gate conductive layer that may include the gate electrode GE of the transistor TR, the first electrode C1 of the capacitor CS, etc. may be disposed on the first gate insulating layer GI1, a second gate insulating layer GI2 may be disposed on the first gate conductive layer, a second gate conductive layer that may include the second electrode C2 of the capacitor CS may be disposed on the second gate insulating layer GI2, an inter-insulating layer ILD may be disposed on the second gate insulating layer GI2 and the second gate conductive layer, a first data conductive layer that may include the first electrode SE and the second electrode DE of the transistor TR may be disposed on the inter-insulating layer ILD, and a planarization layer VIA may be disposed on the first data conductive layer.

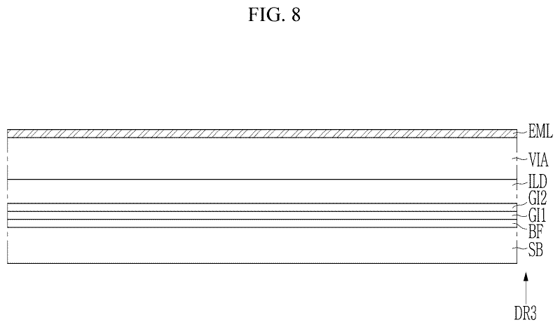

Referring to FIG. 8, an electrode material layer EML may be stacked on the planarization layer VIA.

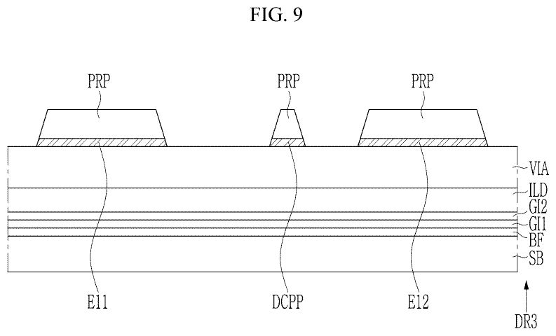

As shown in FIG. 9, a first layer DCPP of the separation patterns DCP1 and DCP2 and the pixel electrodes E1 (refer to FIG. 3), e.g., E11, E12, and E13 (refer to FIG. 4), may be formed by forming a photoresist pattern PRP on the electrode material layer EML and etching the electrode material layer EML using the photoresist pattern PRP as a mask.

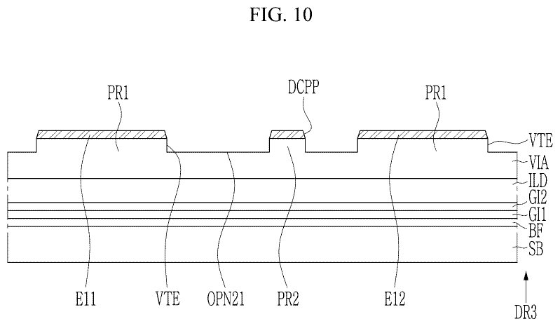

Referring to FIG. 10, the planarization layer VIA may be ashed using the first layer DCPP of the separation patterns DCP1 and DCP2 and the pixel electrodes E1, e.g., E11, E12, and E13, as masks, so that the first protrusions PR1 and the second protrusions PR2 of the planarization layer VIA may be formed by forming a trench VTE in the planarization layer VIA. In this case, the photoresist pattern PRP may be removed.

The first protrusions PR1 of the planarization layer VIA may overlap the pixel electrodes E1, e.g., E11, E12, and E13, and may have substantially the same planar shape as that of the pixel electrodes E1, e.g., E11, E12, and E13, and the second protrusions PR2 of the planarization layer VIA may overlap the first layer DCPP of the separation patterns DCP1 and DCP2 and may have substantially the same planar shape as that of the first layer DCPP of the separation patterns DCP1 and DCP2.

The sidewalls of the first protrusions PR1 and second protrusions PR2 of the planarization layer VIA may have an angle of less than about 20 degrees based on the third direction DR3, so the sidewalls of the first and second protrusions PR1 and PR2 may have a relatively large inclination angle.

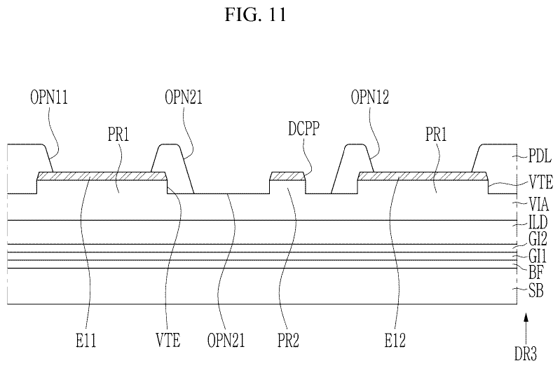

Referring to FIG. 11 together with FIG. 3, an insulating layer may be stacked and photo-etched to form a pixel defining layer PDL defining pixel openings OPN1, e.g., OPN11, OPN12, and OPN13, and separation openings OPN21 and OPN22.

The separation openings OPN21 and OPN22 of the pixel defining layer PDL may be disposed in the trench VTE in the planarization layer VIA, and the sidewalls of the first protrusions PR1 of the planarization layer VIA may be covered by the pixel defining layer PDL.

The second protrusions PR2 of the planarization layer VIA may be spaced apart from the pixel defining layer PDL by the first separation opening OPN21 and the second separation opening OPN22 of the pixel defining layer PDL.

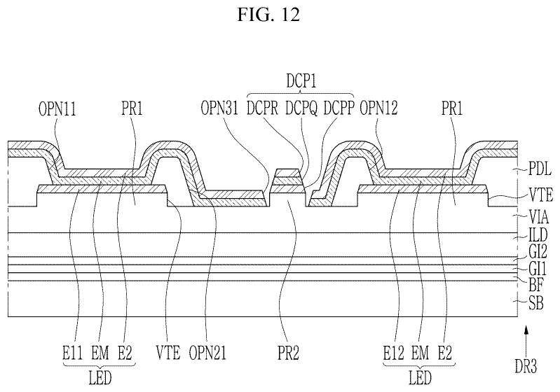

As shown in FIG. 12, the light emitting member EM and the common electrode E2 may be stacked on the pixel defining layer PDL. By the inclination angle of the second protrusions PR2 of the planarization layer VIA, the light emitting member EM and the common electrode E2 may be discontinuously formed on the sidewalls of the second protrusions PR2 of the planarization layer VIA to be broken, and a portion of the broken light emitting member EM and the portion of the broken common electrode E2 may remain on the second protrusions PR2 and become the second layer DCPQ and the third layer DCPR of the separation patterns DCP1 and DCP2.

In addition, the light emitting member EM and the common electrode E2 may be formed discontinuously on the sidewalls of the second protrusions PR2 to be broken within the first separation opening OPN21 and the second separation opening OPN22 of the pixel defining layer PDL disposed within the trench VTE of the planarization layer VIA defining the second protrusions PR2, so a portion disposed on the second protrusions PR2 and a portion disposed in the trench VTE of the planarization layer VIA may be separated from each other, and accordingly, the common layer of the light emitting member EM and the common electrode E2 may define the first opening OPN31 and the second opening OPN32 disposed in a non-light emitting area between neighboring pixels.

In accordance with a manufacturing method for the display device in the illustrated embodiment, the first layer DCPP of the separation patterns DCP1 and DCP2 may be formed together with the pixel electrodes E1, e.g., E11, E12, and E13, when forming pixel electrodes E1, e.g., E11, E12, and E13, the first protrusions PR1 and the second protrusions PR2 of the planarization layer VIA may be formed by ashing the planarization layer VIA using the first layer DCPP of the separation patterns DCP1 and DCP2 and the pixel electrodes E1, e.g., E11, E12, and E13, as masks without an additional ashing mask, and by the inclination angle of the second protrusions PR2 of the planarization layer VIA, and the light emitting member EM and the common electrode E2 may be discontinuously disposed on the sidewalls of the second protrusions PR2 of the planarization layer VIA to be broken so that the common layer of the light emitting member EM and the common electrode E2 may define the first opening OPN31 and the second opening OPN32.

As such, in accordance with the manufacturing method for the display device in the illustrated embodiment, the first opening OPN31 and the second opening OPN32 of the common layer of the light emitting member EM and the common electrode E2 may be defined through the manufacturing process for the display device without an additional mask, so leakage current may be reduced by short-circuiting the light emitting member EM and the common electrode E2 between neighboring pixels while preventing an increase in manufacturing cost or complexity of the manufacturing process, stably driving a high-resolution display device.

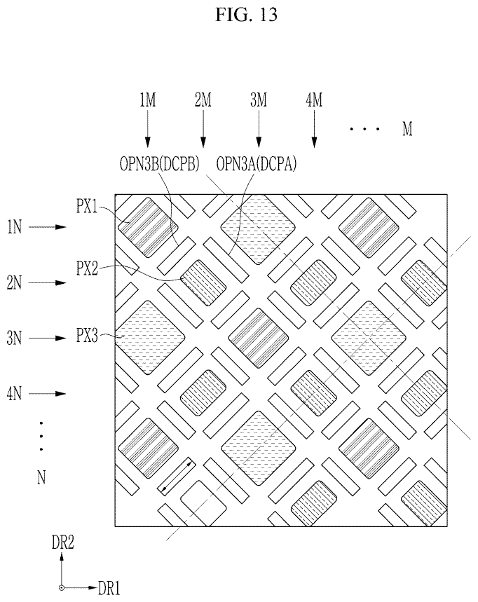

Various embodiments of arrangement of pixels, separation patterns, light emitting members, and openings of common electrodes of display devices according to other embodiments will be described with reference to FIGS. 13 to 16. FIG. 13 to FIG. 16 illustrate a schematic top plan view showing a portion of a display device according to other embodiments.

Referring to FIG. 13, in the display device in the illustrated embodiment, in a first row 1N, a plurality of first pixels PX1 and third pixels PX3 may be arranged alternately, in a neighboring second row 2N, a plurality of second pixels PX2 may be arranged at predetermined intervals, in a neighboring third row 3N, a plurality of third pixels PX3 and first pixels PX1 may be alternately arranged, in a neighboring fourth row 4N, a plurality of second pixels PX2 may be arranged at predetermined intervals, and arrangement of these pixels PX1, PX2, and PX3 may be repeated up to the Nth row.

A plurality of first pixels PX1 and a plurality of third pixels PX3 arranged in the first row 1N and the plurality of second pixels PX2 arranged in the second row 2N may be alternately arranged. Accordingly, in a first column 1M, the first pixels PX1 and third pixels PX3 may be arranged alternately, in a neighboring second column 2M, the second pixels PX2 may be arranged at predetermined intervals, in a neighboring third column 3M, the third pixels PX3 and first pixels PX1 may be alternately arranged, in a neighboring fourth column 4M, the second pixels PX2 may be arranged at predetermined intervals, and the arrangement of these pixels PX1, PX2, and PX3 may be repeated up to an Mth column.

Separation patterns DCPA and an opening OPN3A may be defined between the second pixel PX2 and the third pixel PX3 to correspond to each side of a light emitting area of the third pixel PX3, so as to surround the light emitting area of one third pixel PX3,

In FIG. 13, the separation patterns DCPA and the opening OPN3A are shown as including overlapping edges in a plan view, but the disclosure is not limited thereto, and the edge of the opening OPN3A may be larger than the edge of the separation patterns DCPA, and in a plan view of the display device, the separation patterns DCPA may be disposed within the opening OPN3A.

Separation patterns DCPB and an opening OPN3B may be defined between the first pixel PX1 and the second pixel PX2 to correspond to a side of the first pixel PX1. In FIG. 13, the separation patterns DCPB and the opening OPN3B are shown as including overlapping edges in a plan view, but the disclosure is not limited thereto, and the edge of the opening OPN3B may be larger than the edge of the separation patterns DCPB, and in a plan view of the display device from above, the separation patterns DCPB may be disposed within the opening OPN3B.

Some of the separation patterns DCPA and DCPB may be omitted.

Through the openings OPN3A and OPN3B, the light emitting member EM and the common electrode E2 between neighboring pixels may be short-circuited, thereby reducing leakage current and stably driving a high-resolution display device.

Many features of the display device and the manufacturing method for the display device according to the previously described embodiments are applicable to the display device in the illustrated embodiment.

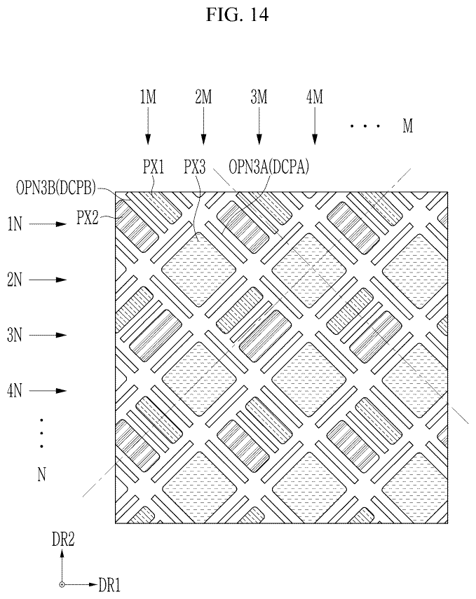

Referring to FIG. 14, in a first row 1N, the first pixels PX1 and the second pixels PX2 may be alternately arranged, in a neighboring second row 2N, the third pixels PX3 may be arranged at predetermined intervals, in a neighboring third row 3N, the second pixels PX2 and the first pixels PX1 may be alternately arranged, in a neighboring fourth row 4N, the third pixels PX3 may be arranged at predetermined intervals, and this arrangement of pixels may be repeated up to the N^{th} row.

The first pixels PX1 and the second pixels PX2 arranged in the first row 1N may be spaced apart in the first diagonal direction R1 and may be arranged parallel to the second diagonal direction R2, and the second pixels PX2 and the first pixels PX1 arranged in the third row 3N are spaced apart in the second diagonal direction R2 and may be arranged parallel to the first diagonal direction R1. Accordingly, in the first column 1M, a pair of first pixels PX1 and second pixels PX2 arranged parallel to the second diagonal direction R2, and a pair of first pixels PX1 and second pixels PX2 arranged parallel to the first diagonal direction R1 may be alternately arranged, in the neighboring second column 2M, the third pixels PX3 may be arranged at predetermined intervals, in the neighboring third column 3M, a pair of first pixels PX1 and second pixels PX2 arranged parallel to the second diagonal direction R2, and a pair of first pixels PX1 and second pixels PX2 arranged parallel to the first diagonal direction R1 may be alternately arranged, in the neighboring second column 2M, the third pixels PX3 may be arranged at predetermined intervals, and this arrangement of pixels may be repeated up to the M^{th} column.

The third pixel PX3 may be larger than the first pixel PX1 and the second pixel PX2.

The separation patterns DCPA and the opening OPN3A may be disposed and defined between the first pixel PX1 and the third pixel PX3 or between the second pixel PX2 and the third pixel PX3 to correspond to each side of the third light emitting area EA3 to surround the third light emitting area EA3 of one third pixel PX3. In FIG. 14, the separation patterns DCPA and the opening OPN3A are shown as including overlapping edges in a plan view, but the disclosure is not limited thereto, and the edge of the opening OPN3A may be larger than the edge of the separation patterns DCPA, and in a plan view of the display device, the separation patterns DCPA may be disposed within the opening OPN3A.

The separation patterns DCPB and the opening OPN3B may be arranged and defined in parallel between the first pixel PX1 and the second pixel PX2. In FIG. 14, the separation patterns DCPB and the opening OPN3B are shown as including overlapping edges in a plan view, but the disclosure is not limited thereto, and the edge of the opening OPN3B may be larger than the edge of the separation patterns DCPB, and in a plan view of the display device, the separation patterns DCPB may be disposed within the opening OPN3B.

Some of the separation patterns DCPA and DCPB may be omitted.

Through the openings OPN3A and OPN3B, the light emitting member EM and the common electrode E2 between neighboring pixels may be short-circuited, thereby reducing leakage current and stably driving a high-resolution display device.

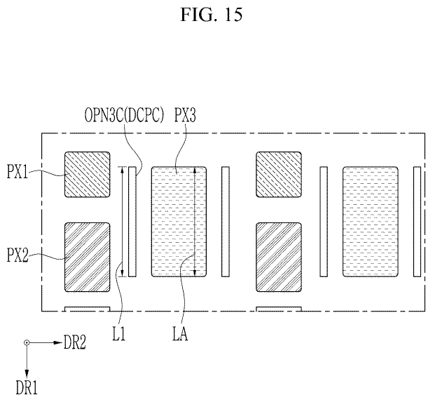

Referring to FIG. 15, arrangement of the pixels of the display device in the illustrated embodiment is similar to the arrangement of the pixels of the display device in the embodiment previously shown in FIG. 4.

The plurality of first pixels PX1 and the plurality of second pixels PX2 may be alternately arranged along the first direction DR1. The third pixel PX3 may be arranged to be spaced apart from the first pixel PX1 and the second pixel PX2 at predetermined intervals along the second direction DR2.

The first pixel PX1, the second pixel PX2, and the third pixel PX3 may each emit light of different wavelengths.

In an embodiment, a driving voltage of the third pixel PX3 may be greater than that of the first and second pixels PX1 and PX2.

In an embodiment, the first pixel PX1, the second pixel PX2, and the third pixel PX3 may each have different areas.

The separation patterns DCPC and the opening OPN3C may be defined between the first pixel PX1 and the third pixel PX3 and between the second pixel PX2 and the third pixel PX3, and may not be disposed between the first pixel PX1 and the second pixel PX2. In FIG. 15, the separation patterns DCPC and the opening OPN3C are shown as having overlapping edges in a plan view, but the disclosure is not limited thereto, and the edge of the opening OPN3C may be larger than the edge of the separation patterns DCPC, and in a plan view of the display device, the separation patterns DCPC may be disposed within the opening OPN3C.

A length L1 of the separation patterns DCPC and the opening OPN3C may be substantially equal to a length LA of the third pixel PX3.

By the separation patterns DCPC and the opening OPN3C, common layers between the first pixel PX1 and the third pixel PX3 and between the second pixel PX2 and the third pixel PX3—for example, the light emitting member EM and the common electrode E2 between neighboring pixels—may be short-circuited, so leakage current may be reduced, and high-resolution display devices may be driven stably.

The separation patterns DCPC and the opening OPN3C may not be disposed and defined between the first pixel PX1 and the second pixel PX2, which are driven at a relatively low driving voltage and have a relatively small effect of leakage current, and accordingly, a voltage drop in the common voltage applied to the common electrode E2 may be prevented.

Many features of the display device and the manufacturing method for the display device according to the previously described embodiments are applicable to the display device in the illustrated embodiment.

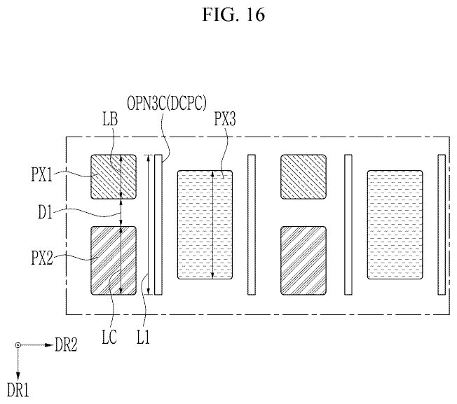

Referring to FIG. 16, the display device in the illustrated embodiment is similar to the display device in the embodiment described with reference to FIG. 15.

Referring to FIG. 16, the length L1 of the separation patterns DCPC and the opening OPN3C may be substantially the same as or greater than a sum of a length LB of the first pixel PX1, a length LC of the second pixel PX2, and a distance D1 between the first pixel PX1 and the second pixel PX2. In FIG. 16, the separation patterns DCPC and the opening OPN3C are shown as including overlapping edges in a plan view, but the disclosure is not limited thereto, and the edge of the opening OPN3C may be larger than the edge of the separation patterns DCPC, and in a plan view of the display device, the separation patterns DCPC may be disposed within the opening OPN3C.

Leakage current between the first pixel PX1, the second pixel PX2, and the third pixel PX3 may be further reduced by forming the separation patterns DCPC and the opening OPN3C with a long length in the side surfaces of the first pixel PX1 and the second pixel PX2.

In addition, the separation patterns DCPC and the opening OPN3C may not be disposed and defined between the first pixel PX1 and the second pixel PX2, which are driven at a relatively low driving voltage and have a relatively small effect of leakage current, and accordingly, a voltage drop in the common voltage applied to the common electrode E2 may be prevented.

Many features of the display device and the manufacturing method for the display device according to the previously described embodiments are applicable to the display device in the illustrated embodiment.

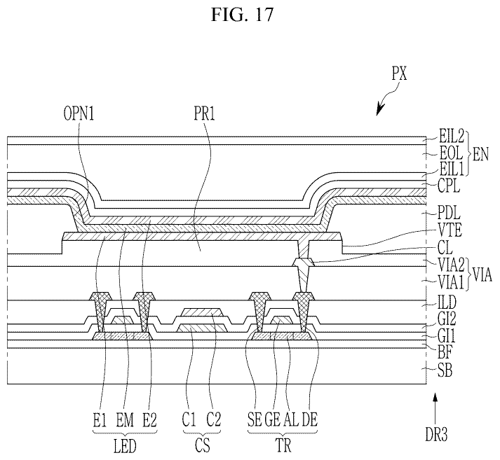

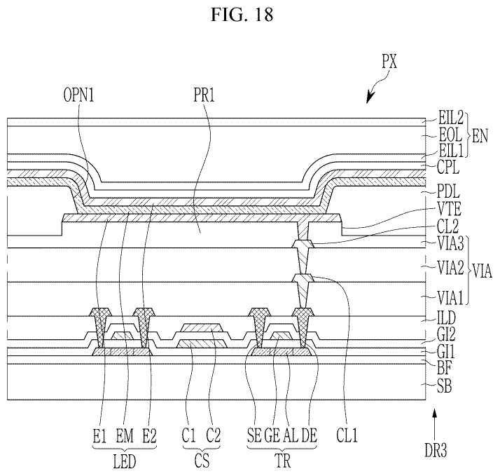

Now, a structure of one pixel of a display device according to other embodiments will be briefly described with reference to FIGS. 17 and 18. FIG. 17 and FIG. 18 illustrate a cross-sectional view of one pixel of a display device according to other embodiments.

Referring to FIG. 17, the structure of one pixel of the display device in the illustrated embodiment is similar to the structure of one pixel of the display device in the embodiment described with reference to FIG. 3. Below, detailed descriptions of the same components will be omitted.

Referring to FIG. 17, the planarization layer VIA may include a first planarization layer VIA1 and a second planarization layer VIA2, the pixel electrode E1 may be disposed on the second planarization layer VIA2 of the planarization layer VIA, and the pixel electrode E1 may be connected to the transistor TR through a connector CL. The pixel defining layer PDL may be disposed on the second planarization layer VIA2, and the previously described protrusions PR1 and PR2 and the trench VTE of the planarization layer VIA may be formed in the second planarization layer VIA2.

Many features of the display device and the manufacturing method for the display device according to the previously described embodiments are applicable to the display device in the illustrated embodiment.

Referring to FIG. 18, the structure of one pixel of the display device in the illustrated embodiment is similar to the structure of one pixel of the display device in the embodiment described with reference to FIG. 3 and FIG. 17. Below, detailed descriptions of the same components will be omitted.

Referring to FIG. 18, the planarization layer VIA may include a first planarization layer VIA1, a second planarization layer VIA2, and a third planarization layer VIA3, the pixel electrode E1 may be disposed on the third planarization layer VIA3 of the planarization layer VIA, and the pixel electrode E1 may be connected to the transistor TR through two connectors CL1 and CL2.

The pixel defining layer PDL may be disposed on the third planarization layer VIA3, and the previously described protrusions PR1 and PR2 and the trench VTE of the planarization layer VIA may be formed in the third planarization layer VIA3.

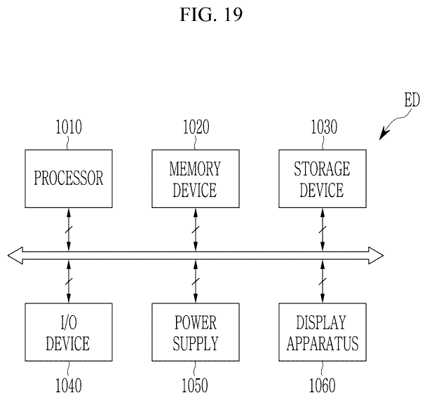

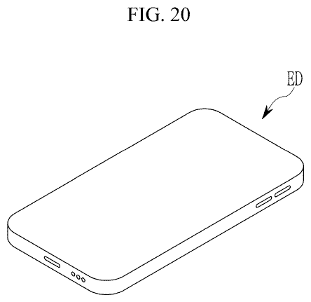

FIG. 19 is a block diagram illustrating an embodiment of an electronic device. FIG. 20 is a view illustrating an embodiment of the electronic device of FIG. 19 implemented as a smartphone.

Referring to FIGS. 19 and 20, in an embodiment, an electronic device ED may include a processor 1010, a memory device 1020, a storage device 1030, an input/output (“I/O”) device 1040, a power supply 1050, and a display device 1060. Here, the display device 1060 may correspond to the display device 1000 of FIG. 1. The electronic device ED may further include a plurality of ports for communicating with a video card, a sound card, a memory card, a universal serial bus (“USB”) device, or the like. In an embodiment, the electronic device ED may be implemented as a television. In another embodiment, the electronic device ED may be implemented as a smart phone. However, embodiments are not limited thereto, in another embodiment, the electronic device ED may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 1010 may perform various computing functions. In an embodiment, the processor 1010 may be a microprocessor, a central processing unit (“CPU”), an application processor (“AP”), or the like. The processor 1010 may be coupled to other components via an address bus, a control bus, a data bus, or the like. In an embodiment, the processor 1010 may be coupled to an extended bus such as a peripheral component interconnection (“PCI”) bus.

The memory device 1020 may store data for operations of the electronic device ED. In an embodiment, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 1030 may include a solid state drive (“SSD”) device, a hard disk drive (“HDD”) device, a CD-ROM device, or the like. In an embodiment, the I/O device 1040 may include an input device such as a keyboard, a keypad, a mouse device, a touchpad, a touch-screen, or the like, and an output device such as a printer, a speaker, or the like.

The power supply 1050 may provide power for operations of the electronic device ED. The power supply 1050 may provide power to the display device 1060. The display device 1060 may be coupled to other components via the buses or other communication links. In an embodiment, the display device 1060 may be included in the I/O device 1040.

In an embodiment the electronic device may be implemented as a smartphone. However the embodiments of the present disclosure may be exemplary and may not be limited to this. For example, the electronic device ED may be implemented as a mobile phone, a video phone, a smart pad, a smart watch, a television, a tablet PC, a vehicle display, a computer monitor, a notebook computer, a head-mounted display device, etc. In addition, the electronic device ED may be a television, a monitor, a notebook computer, or a tablet. In addition, the electronic device ED may be a car.

Many features of the display device and the manufacturing method for the display device according to the previously described embodiments are applicable to the display device in the illustrated embodiment.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the appended claims.

What is claimed is:

1. A display device comprising:
an insulating layer including:
a protrusion which is disposed between a first pixel and a second pixel which are next to each other and protrudes along a height direction;
a first pixel electrode disposed in the first pixel and a second pixel electrode disposed in the second pixel on the insulating layer and; and
a common electrode disposed on the first pixel electrode and the second pixel electrode and connected across the first pixel and the second pixel,
wherein the common electrode defines an opening between the first pixel and the second pixel, and
the opening of the common electrode surrounds a sidewall of the protrusion.

2. The display device of claim 1, wherein
the sidewall of the protrusion of the insulating layer has an inclination of less than about 20 degrees with respect to the height direction.

3. The display device of claim 1, further comprising
a separation pattern disposed on the protrusion of the insulating layer,
wherein the separation pattern includes a first layer including a same material as a material of the first pixel electrode and the second pixel electrode.

4. The display device of claim 3, further comprising
a light emitting member disposed between the first and second pixel electrodes and the common electrode,
wherein the light emitting member includes a common layer including portions which are connected to each other across the first pixel and the second pixel, and
the common layer of the light emitting member defines the opening.

5. The display device of claim 4, wherein
the separation pattern further includes a second layer including a same material as a material of the common layer, and
a third layer including a same material as a material of the common electrode.

6. The display device of claim 1, further comprising
a pixel defining layer defining pixel openings corresponding to each of the first pixel and the second pixel and a separation opening surrounding the protrusion of the insulating layer.

7. The display device of claim 6, wherein
the insulating layer further includes first protrusions overlapping each of the first pixel electrode and the second pixel electrode and protruding in the height direction, and
sidewalls of the first protrusions have substantially a same planar shape as a planar shape of each of the first pixel electrode and the second pixel electrode.

8. The display device of claim 7, wherein
the sidewalls of the first protrusions of the insulating layer have an inclination of less than about 20 degrees with respect to the height direction.

9. The display device of claim 8, wherein
the sidewalls of the first protrusions of the insulating layer are covered with the pixel defining layer.

10. The display device of claim 7, wherein
the insulating layer has trench defining the protrusion and the first protrusions, and
the separation opening of the pixel defining layer is defined within the trench.

11. The display device of claim 10, wherein
the opening of the common electrode is defined within the trench.

12. The display device of claim 11, further comprising
a separation pattern disposed on the protrusion of the insulating layer,
wherein
the opening of the common electrode is surrounded by the separation opening of the pixel defining layer when viewed from above in the height direction.

13. The display device of claim 12, wherein
the separation pattern and the sidewall of the protrusion are not covered with the pixel defining layer.

14. A manufacturing method for a display device, the method comprising:
forming a transistor on a substrate;
stacking an insulating layer on the transistor;
forming a first pixel electrode and a second pixel electrode of a first pixel and a second pixel next to each other on the insulating layer, and forming a separation pattern disposed between the first pixel electrode and the second pixel electrode;
forming first protrusions which overlap each of the first pixel electrode and the second pixel electrode and protrude in a height direction, a second protrusion overlapping the separation pattern and protruding in the height direction, and a trench defining the first and the second protrusions by ashing the insulating layer using the first pixel electrode, the second pixel electrode, and the separation pattern as masks;
forming a pixel defining layer defining pixel openings overlapping each of the first pixel electrode and the second pixel electrode and a separation opening surrounding the second protrusion; and
stacking a light emitting member and a common electrode on the pixel defining layer,
wherein the common electrode is formed to define an opening between the first pixel and the second pixel and surrounding a sidewall of the second protrusion.

15. The manufacturing method of claim 14, wherein
the sidewall of the second protrusion of the insulating layer is formed to have an inclination of less than about 20 degrees with respect to the height direction.

16. The manufacturing method of claim 14, wherein
the separation pattern includes a first layer formed from a same layer as a layer of the first pixel electrode and the second pixel electrode,
a second layer disposed on the first layer and formed from a same layer as a layer of the light emitting member, and
a third layer disposed on the second layer and formed from a same layer as a layer of the common electrode.

17. The manufacturing method of claim 14, wherein
sidewalls of the first protrusions of the insulating layer are covered with the pixel defining layer.

18. The manufacturing method of claim 14, wherein
the separation opening of the pixel defining layer is defined within the trench.

19. The manufacturing method of claim 18, wherein
the opening of the common electrode is defined within the trench.

20. The manufacturing method of claim 14, wherein
the light emitting member includes a common layer including portions which are connected to each other across the first pixel and the second pixel, and
the common layer of the light emitting member defines the opening.

21. An electronic device comprising:
a display device comprising:
an insulating layer including:
a protrusion which is disposed between a first pixel and a second pixel which are next to each other and protrudes along a height direction;
a first pixel electrode disposed in the first pixel and a second pixel electrode disposed in the second pixel on the insulating layer and; and
a common electrode disposed on the first pixel electrode and the second pixel electrode and connected across the first pixel and the second pixel,
wherein the common electrode defines an opening between the first pixel and the second pixel, and
the opening of the common electrode surrounds a sidewall of the protrusion.

22. The electronic device of claim 21, wherein
the sidewall of the protrusion of the insulating layer has an inclination of less than about 20 degrees with respect to the height direction.

23. The electronic device of claim 21, further comprising
a separation pattern disposed on the protrusion of the insulating layer,
wherein the separation pattern includes a first layer including a same material as a material of the first pixel electrode and the second pixel electrode.

24. The electronic device of claim 23, further comprising
a light emitting member disposed between the first and second pixel electrodes and the common electrode,
wherein the light emitting member includes a common layer including portions which are connected to each other across the first pixel and the second pixel, and
the common layer of the light emitting member defines the opening.

25. The electronic device of claim 24, wherein
the separation pattern further includes a second layer including a same material as a material of the common layer, and
a third layer including a same material as a material of the common electrode.

26. The electronic device of claim 21, further comprising
a pixel defining layer defining pixel openings corresponding to each of the first pixel and the second pixel and a separation opening surrounding the protrusion of the insulating layer.
